(19) United States
(12) Patent Application Publication
(10) Pub. No.: US 2025/0136734 A1
(43) Pub. Date: May 1, 2025

(54) PROTECTIVE-FILM FORMING COMPOSITION

(71) Applicant: NISSAN CHEMICAL CORPORATION, Tokyo (JP)

(72) Inventors: Tokio NISHITA, Toyama-shi (JP); Kazuhiko KINOSHITA, Toyama-shi (JP)

(73) Assignee: NISSAN CHEMICAL CORPORATION, Tokyo (JP)

(21) Appl. No.: 18/835,499

(22) PCT Filed: Feb. 10, 2023
(86) PCT No.: PCT/JP2023/004629

§ 371 Date: Aug. 2, 2024

(30) Foreign Application Priority Data
Feb. 16, 2022 (JP) 2022-022120

(51) Int. Cl. C08F 220/32; C08G 65/18; C08J 5/18; G03F 7/11; G03F 7/16; G03F 7/40

(52) U.S. Cl. CPC C08F 220/325; C08G 65/18; C08J 5/18; G03F 7/11; G03F 7/168; G03F 7/40

(57) ABSTRACT

A protective-film forming composition for forming a protective film that protects an inorganic film formed on a surface of a semiconductor substrate against wet etching, the composition containing: a polymer that contains no aromatic ring in a main chain and contains at least one of an oxirane ring and an oxetane ring; and a solvent.

### TECHNICAL FIELD

The present invention relates to a composition for forming a protective film excellent in particularly resistance to a semiconductor wet etching solution and an ozonated solution in a lithography process in semiconductor manufacturing. The present invention also relates to a protective film formed from the composition, a method for manufacturing a substrate with a resist pattern to which the protective film is applied, and a method for manufacturing a semiconductor device.

### BACKGROUND ART

In semiconductor manufacturing, a lithography process of providing a resist under layer film between a substrate and a resist film formed the substrate and forming a resist pattern having a desired shape is widely known. The substrate is processed after the resist pattern is formed, and dry etching is mainly used as the process, but wet etching may be used depending on the type of substrate. Patent Literature 1 discloses a resist under layer film material having resistance to an aqueous alkaline hydrogen peroxide solution.

### CITATION LIST

### Patent Literature

Patent Literature 1: JP 2018-173520 A

### SUMMARY OF INVENTION

### Technical Problem

In a case where a protective film for a semiconductor substrate is formed by using a protective-film forming composition, and a base substrate is processed by wet etching, with the protective film used as an etching mask, it is demanded for the protective film to have a good masking function (that is, the masked part can protect the substrate) against a semiconductor wet etching solution.

In addition, in recent years, an ozonated solution may be used to clean a semiconductor substrate during a lithography process. Therefore, the protective film is required to have good resistance to the ozonated solution.

The present invention has been made in view of the above circumstances, and an object thereof is to provide a protective-film forming composition that enables the formation of a protective film excellent in resistance to a semiconductor wet etching solution and an ozonated solution. The present invention also relates to a protective film formed from the protective-film forming composition, a method for manufacturing a substrate with a resist pattern to which the protective film is applied, and a method for manufacturing a semiconductor device.

### Solution to Problem

As a result of intensive studies to solve the above-described problems, the present inventors have found that the above-described problems can be solved by using, as a polymer contained in a protective-film forming composition, a polymer that contains no aromatic ring in a main chain and contains at least one of an oxirane ring and an oxetane ring, and have completed the present invention.

That is, the present invention includes the following aspects.

[1] A protective-film forming composition for forming a protective film that protects an inorganic film formed on a surface of a semiconductor substrate against wet etching, the composition containing:
a polymer that contains no aromatic ring in a main chain and contains at least one of an oxirane ring and an oxetane ring; and a solvent.

[2] The protective-film forming composition according to [1], wherein the polymer satisfies at least one of (i) and (ii) shown below:
(i) containing at least one of a group represented by Formula (Ox-1) and a group represented by Formula (Ox-2) as a group containing the oxirane ring; and
(ii) containing a group represented by Formula (Ox-3) as a group containing the oxetane ring,

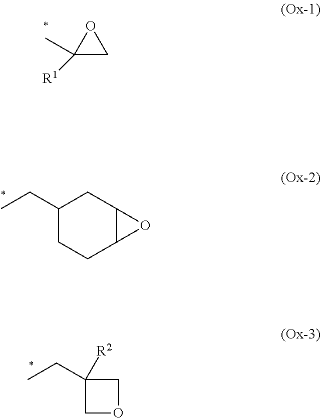

wherein, * represents a bond; and R¹ and R² each independently represent a hydrogen atom, a methyl group, or an ethyl group.

[3] The protective-film forming composition according to [1] or [2], wherein the polymer is at least one of a polymer (P-1) that is obtained from at least a compound having a polymerizable unsaturated double bond and a polymer (P-2) that is represented by Formula (p-2),

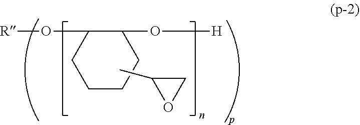

wherein, R″ is a group obtained by removing p number of hydroxyl groups (—OH) from a structural formula of a p-hydric alcohol; and p and n each represent an integer of 1 or greater.

[4] The protective-film forming composition according to [3], wherein the polymer (P-1) contains a repeating unit represented by Formula (p-1),

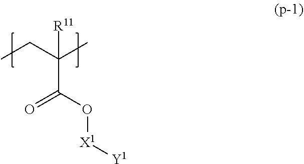

wherein, R¹¹ represents a hydrogen atom or a methyl group; Y¹ represents any one of Formula (Ox-1), Formula (Ox-2), or Formula (Ox-3); when Y¹ is Formula (Ox-1), X¹ represents a methylene group; and when Y¹ is Formula (Ox-2) or (Ox-3), X¹ represents a single bond,

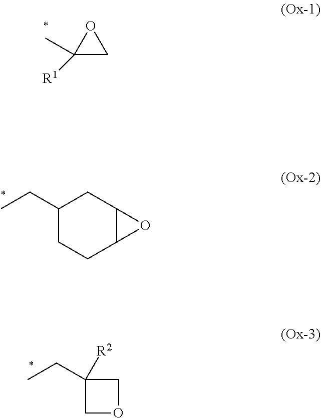

wherein, * represents a bond; and R¹ and R² each independently represent a hydrogen atom, a methyl group, or an ethyl group.

[5] The protective-film forming composition according to any one of [1] to [4], further containing a crosslinking catalyst.

[6] The protective-film forming composition according to any one of [1] to [5], further containing a crosslinking agent.

[7] A protective film against a semiconductor wet etching solution, wherein the protective film includes a baked product of a coating film formed of the protective-film forming composition according to any one of [1] to [6].

[8] A method for manufacturing a substrate with a protective film, the method including a step of applying the protective-film forming composition according to any one of [1] to [6] on a stepped semiconductor substrate and baking the protective-film forming composition to form a protective film.

[9] A method for manufacturing a substrate with a resist pattern used in semiconductor manufacturing, the method including:
a step of applying the protective-film forming composition according to any one of [1] to [6] on a semiconductor substrate and baking the protective-film forming composition to form a protective film as a resist under layer film; and
a step of forming a resist film directly on the protective film or over the protective film, with another layer interlayered, and exposing and developing the resist film to form a resist pattern.

[10] A method for manufacturing a semiconductor device, the method including a step of forming a protective film by using the protective-film forming composition according to any one of [1] to [6] on a semiconductor substrate having a surface on which an inorganic film is formed, forming a resist pattern directly on the protective film or over the protective film, with another layer interlayered, dry etching the protective film by using the resist pattern as a mask to expose a surface of the inorganic film, and performing wet etching on the inorganic film by using the protective film after the dry etching as a mask with a semiconductor wet etching solution.

### Advantageous Effects of Invention

According to the present invention, it is possible to provide the protective-film forming composition that enables the formation of the protective film excellent in resistance to the semiconductor wet etching solution and the ozonated solution. According to the present invention, it is also possible to provide the protective film formed from the protective-film forming composition, the method for manufacturing a substrate with a resist pattern to which the protective film is applied, and the method for manufacturing a semiconductor device.

### DESCRIPTION OF EMBODIMENTS

### (Protective-Film Forming Composition)

A protective-film forming composition of the present invention is a composition for forming a protective film.

The protective film protects an inorganic film that is formed on a surface of the semiconductor substrate against wet etching.

The protective-film forming composition contains a polymer and a solvent.

### <Polymer (P)>

The polymer has no aromatic ring in the main chain.

The polymer has at least one of an oxirane ring and an oxetane ring.

In the present specification, the above-described polymer may be referred to as a “polymer (P)”.

The polymer (P) preferably has no aromatic ring.

The main chain of the polymer refers to a portion composed of the longest chain of atoms in the polymer. In a case where an atom constituting an aromatic ring is present among the atoms constituting the chain, the polymer contains the aromatic ring in the main chain.

In addition, in a case where an aromatic ring is not present in the polymer, the polymer does not contain an aromatic ring in the main chain even though it is difficult to determine the main chain of the polymer.

Examples of the aromatic ring include aromatic hydrocarbon rings and aromatic heterocyclic rings. Examples of the aromatic hydrocarbon ring include benzene rings, naphthalene rings, anthracene rings, and other aromatic hydrocarbon rings.

Aromatic rings (particularly aromatic hydrocarbon rings) are easily decomposed by ozone. Therefore, in a case where an aromatic ring is present in the main chain of the polymer, the aromatic ring in the main chain of the polymer is decomposed by ozone, and the polymer tends to have a low molecular weight. As a result, the protective film formed by using the polymer is easily deteriorated by exposure to ozone.

Therefore, since the polymer does not contain the aromatic ring in the main chain, the protective film formed by using the aforementioned polymer is more excellent in resistance to ozone than a protective film formed by using a polymer that contains an aromatic ring in the main chain.

Even though the side chain has an aromatic ring, the decomposition of the side chain is less likely to affect the reduction in molecular weight of the polymer. Therefore, the polymer (P) may contain an aromatic ring in the side chain. However, the absence of an aromatic ring in the side chain is also more excellent in resistance to ozone. The polymer (P) preferably contains no aromatic ring from the viewpoint as described above.

From the viewpoint of suitably obtaining the effects of the present invention, the polymer (P) preferably satisfies at least one of (i) and (ii) shown below:
(i) containing at least one of a group represented by Formula (Ox-1) and a group represented by Formula (Ox-2) as a group containing an oxirane ring; and
(ii) containing a group represented by Formula (Ox-3) as a group containing an oxetane ring.

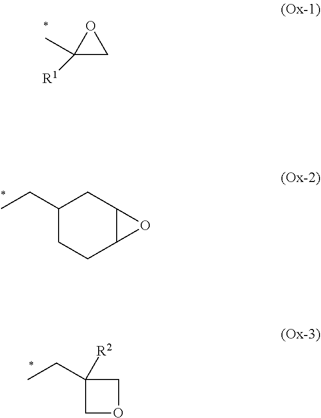

(In Formulae (Ox-1) to (Ox-3), * represents a bond, and R¹ and R² each independently represent a hydrogen atom, a methyl group, or an ethyl group.)

From the viewpoint of suitably obtaining the effects of the present invention, the polymer (P) preferably satisfies at least one of a polymer (P-1) and a polymer (P-2) shown below:
the polymer (P-1) being a polymer that is obtained from at least a compound having a polymerizable unsaturated double bond; and
the polymer (P-2) being a polymer represented by Formula (p-2).

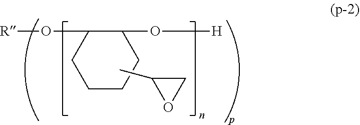

(In Formula (p-2), R″ is a group obtained by removing p number of hydroxyl groups (—OH) from a structural formula of a p-hydric alcohol, and p and n each represent an integer of 1 or greater.)

### <<Polymer (P-1)>>

The polymer (P-1) is a polymer that is obtained from at least a compound having a polymerizable unsaturated double bond. In other words, the polymer (P-1) is a polymer obtained by polymerizing one or two compounds having a polymerizable unsaturated double bond.

Examples of the polymerizable unsaturated double bond include polymerizable carbon-carbon double bonds contained in an acryloyl group, a methacryloyl group, a vinyl group, an allyl group, a styryl group, and other groups.

The polymer (P-1) preferably has a repeating unit represented by Formula (p-1).

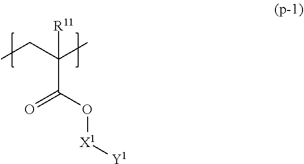

(In Formula (p-1), R¹¹ represents a hydrogen atom or a methyl group, Y¹ represents any one of Formula (Ox-1), Formula (Ox-2), or Formula (Ox-3), when Y¹ is Formula (Ox-1), X¹ represents a methylene group, and when Y¹ is Formula (Ox-2) or (Ox-3), X¹ represents a single bond.)

Examples of the compound having a polymerizable unsaturated double bond that gives rise to the repeating unit represented by Formula (p-1) in the polymer (P-1) include glycidyl acrylate, glycidyl methacrylate, oxetan-3-yl methyl acrylate, oxetan-3-yl methyl methacrylate, (3-ethyloxetan-3-yl)methyl acrylate, (3-ethyloxetan-3-yl)methyl methacrylate, 3,4-epoxycyclohexyl methyl acrylate, 3,4-epoxycyclohexyl methyl methacrylate, and other compounds.

From the viewpoint of suitably obtaining the effects of the present invention, the polymer (P-1) preferably has a repeating unit represented by Formula (p-a).

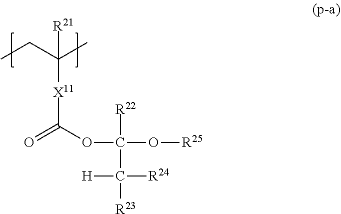

(In Formula (p-a), X¹¹ represents a single bond or a divalent organic group, R²¹ represents a hydrogen atom or a methyl group, R²² to R²⁴ each independently represent a hydrogen atom or an alkyl group having 1 to 10 carbon atoms, R²⁵ represents an alkyl group having 1 to 10 carbon atoms, and R²⁴ and R²⁵ may be bonded to each other to form a ring.)

The repeating unit represented by Formula (p-a) has the hemiacetal ester structure, which is easily decomposed in the presence of a catalyst to produce a carboxyl group. Therefore, in a case where the polymer (P-1) has the repeating unit represented by Formula (p-a), the polymer (P-1) can easily form a crosslinking structure by the reaction of the produced carboxyl group with an oxirane ring or an oxetane ring. The formation of the crosslinking structure enables solvent resistance to be enhanced when a coating film is applied to the upper side of the protective film, and enables reduction of variation of film thicknesses or other factors, which is caused by heat generated when a vapor deposition film is produced by CVD or other methods.

Examples of the divalent organic group in X¹¹ include phenylene groups.

Examples of the alkyl group having 1 to 10 carbon atoms include methyl groups, ethyl groups, normal butyl groups, normal octyl groups, isopropyl groups, tert-butyl groups, 2-ethylhexyl groups, and cyclohexyl groups.

In addition, R²⁴ and R²⁵ may be bonded to each other to form a ring, and examples of the ring thus formed include a tetrahydrofuran ring, a tetrahydropyran ring, and other rings.

A compound having a polymerizable unsaturated double bond that gives rise to the repeating unit represented by Formula (p-a) in the polymer (P-1) can be synthesized by, for example, the method described in paragraphs [0012] to [0015] of JP 5077564 B2.

Examples of the compound having a polymerizable unsaturated double bond that gives rise to the repeating unit represented by Formula (p-a) to the polymer (P-1) include methacrylic acid hemiacetal ester compounds, acrylic acid hemiacetal ester compounds, and other compounds.

Examples of the methacrylic acid hemiacetal ester compounds include 1-methoxyethyl methacrylate, 1-ethoxyethyl methacrylate, 1-isopropoxyethyl methacrylate, 1-normal butoxyethyl methacrylate, 1-normal hexyloxyethyl methacrylate, tetrahydro-2H-pyran-2-yl-methacrylate, and other methacrylic acid hemiacetal ester compounds.

Examples of the acrylic acid hemiacetal ester compounds include 1-methoxyethyl acrylate, 1-tert-butoxyethyl acrylate, 1-isopropoxyethyl acrylate, 1-normal butoxyethyl acrylate, tetrahydro-2H-pyran-2-yl-acrylate, and other acrylic acid hemiacetal ester compounds.

The polymer (P-1) may have other repeating units.

Examples of the compound having a polymerizable unsaturated double bond that gives rise to another repeating unit in the polymer (P-1) include acrylic acid ester compounds, methacrylic acid ester compounds, acrylamide compounds, methacrylamide compounds, vinyl compounds, styrene compounds, maleimide compounds, maleic anhydrides, acrylonitrile, and other compounds.

Examples of the acrylic acid ester compounds include methyl acrylate, ethyl acrylate, isopropyl acrylate, benzyl acrylate, naphthyl acrylate, anthryl acrylate, anthryl methyl acrylate, phenyl acrylate, 2-hydroxyethyl acrylate, 2-hydroxypropyl acrylate, 2,2,2-trifluoroethyl acrylate, 4-hydroxybutyl acrylate, isobutyl acrylate, tert-butyl acrylate, cyclohexyl acrylate, isobornyl acrylate, 2-methoxyethyl acrylate, methoxytriethylene glycol acrylate, 2-ethoxyethyl acrylate, tetrahydrofurfuryl acrylate, 3-methoxybutyl acrylate, 2-methyl-2-adamantyl acrylate, 2-ethyl-2-adamantyl acrylate, 2-propyl-2-adamantyl acrylate, 2-methoxybutyl-2-adamantyl acrylate, 8-methyl-8-tricyclodecyl acrylate, 8-ethyl-8-tricyclodecyl acrylate, 5-acryloyloxy-6-hydroxynorbornene-2-carboxylic-6-lactone, and other acrylic acid ester compounds.

Examples of the methacrylic acid ester compounds include ethyl methacrylate, normal propyl methacrylate, normal pentyl methacrylate, cyclohexyl methacrylate, benzyl methacrylate, naphthyl methacrylate, anthryl methacrylate, anthryl methyl methacrylate, phenyl methacrylate, 2-phenylethyl methacrylate, 2-hydroxyethyl methacrylate, 2-hydroxypropyl methacrylate, 2,2,2-trifluoroethyl methacrylate, 2,2,2-trichloroethyl methacrylate, methyl acrylate, isobutyl methacrylate, 2-ethylhexyl methacrylate, isodecyl methacrylate, normal lauryl methacrylate, normal stearyl methacrylate, methoxydiethylene glycol methacrylate, methoxypoly ethylene glycol methacrylate, tetrahydrofurfuryl methacrylate, isobornyl methacrylate, tert-butyl methacrylate, isostearyl methacrylate, normal butoxyethyl methacrylate, 3-chloro-2-hydroxypropyl methacrylate, 2-methyl-2-adamantyl methacrylate, 2-ethyl-2-adamantyl methacrylate, 2-propyl-2-adamantyl methacrylate, 2-methoxybutyl-2-adamantyl methacrylate, 8-methyl-8-tricyclodecyl methacrylate, 8-ethyl-8-tricyclodecyl methacrylate, 5-methacryloyloxy-6-hydroxynorbornene-2-carboxylic-6-lactone, 2,2,3,3,4,4,4-heptafluorobutyl methacrylate, and other methacrylic acid ester compounds.

Examples of the acrylamide compounds include acrylamide, N-methylacrylamide, N-ethylacrylamide, N-benzylacrylamide, N-phenylacrylamide, N,N-dimethylacrylamide, and other acrylamide compounds.

Examples of methacrylic acid amide compounds include methacrylamide, N-methylmethacrylamide, N-ethylmethacrylamide, N-benzylmethacrylamide, N-phenylmethacrylamide, N,N-dimethylmethacrylamide, and other methacrylic acid amide compounds.

Examples of the vinyl compounds include vinyl ether, methyl vinyl ether, benzyl vinyl ether, 2-hydroxyethyl vinyl ether, phenyl vinyl ether, propyl vinyl ether, and other vinyl compounds.

Examples of the styrene compounds include styrene, methylstyrene, chlorostyrene, bromostyrene, hydroxystyrene, and other styrene compounds.

Examples of the maleimide compounds include maleimide, N-methylmaleimide, N-phenylmaleimide, N-cyclohexylmaleimide, and other maleimide compounds.

The polymer (P-1) can be obtained by the polymerization of one or two compounds having a polymerizable unsaturated double bond.

The polymerization method is not particularly limited, and for example, the polymer (P-1) can be produced by dissolving a compound (monomer) having a polymerizable unsaturated double bond and a chain transfer agent added as necessary in an organic solvent, adding a polymerization initiator and performing a polymerization reaction, and adding a polymerization terminator as necessary.

The addition amount of the polymerization initiator is, for example, 1% to 10% by mass with respect to the mass of the monomer.

The addition amount of the polymerization terminator is, for example, 0.01% to 0.2% by mass with respect to the mass of the monomer.

The used organic solvent is not particularly limited, and examples thereof include propylene glycol monomethyl ether, propylene glycol monopropyl ether, ethyl lactate, dimethylformamide, and other organic solvents.

Examples of the used chain transfer agent include dodecanethiol, dodecylthiol, and other chain transfer agents.

Examples of the used polymerization initiator include azobisisobutyronitrile, azobiscyclohexanecarbonitrile, and other polymerization initiators.

Examples of the used polymerization terminator include 4-methoxyphenol and other polymerization terminators.

The reaction temperature is, for example, 30° C. to 100° C.

The reaction time is, for example, 1 to 48 hours.

The weight-average molecular weight of the polymer (P-1) is not particularly limited, and is preferably 1,000 to 500,000, more preferably 3,000 to 150,000, and particularly preferably 5,000 to 50,000.

In a case where the polymer (P-1) has the repeating unit represented by Formula (p-1), the ratio of the number of moles of the repeating unit represented by Formula (p-1) to the total number of moles of the repeating units in the polymer (P-1) is not particularly limited, and is preferably 1% by mol to 50% by mol, more preferably 5% by mol to 40% by mol, and particularly preferably 10% by mol to 30% by mol from the viewpoint of suitably obtaining the effects of the present invention.

In a case where the polymer (P-1) has the repeating unit represented by Formula (p-a), the ratio of the number of moles of the repeating unit represented by Formula (p-a) to the total number of moles of the repeating units in the polymer (P-1) is not particularly limited, and is preferably 1% by mol to 50% by mol, more preferably 5% by mol to 40% by mol, and particularly preferably 10% by mol to 30% by mol from the viewpoint of suitably obtaining the effects of the present invention.

In a case where the polymer (P-1) has the repeating unit represented by Formula (p-1) and the repeating unit represented by Formula (p-a), the ratio ([p-1]:[p-a]) of the number of moles of the repeating unit ([p-1]) represented by Formula (p-1) in the polymer (P-1) to the number of moles of the repeating unit ([p-a]) represented by Formula (p-a) in the polymer (P-1) is preferably 0.1:1 to 1:0.1, more preferably 0.4:1 to 1:0.4, and particularly preferably 0.6:1 to 1:0.6 from the viewpoint of suitably obtaining the effects of the present invention.

The polymer (P-1) does not contain an aromatic ring in the main chain, but may contain an aromatic ring in a side chain. However, the amount thereof is preferably small. In this regard, the ratio of the number of moles of a repeating unit containing an aromatic ring in a side chain in the polymer (P-1) to the total number of moles of the repeating units is preferably 0% by mol to 20% by mol, more preferably 0% by mol to 10% by mol, still more preferably 0% by mol to 5% by mol, and most preferably 0% by mol to 1% by mol.

### <<Polymer (P-2)>>

A polymer (P-2) is represented by Formula (p-2).

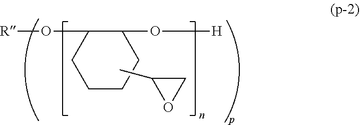

(In Formula (p-2), R″ is a group obtained by removing p number of hydroxyl groups (—OH) from a structural formula of a p-hydric alcohol, and p and n each represent an integer of 1 or greater.)

Examples of the p-hydric alcohol [R″(OH)p] include polyhydric alcohols (such as alcohols having 1 to 15 carbon atoms) such as 2,2-bis(hydroxymethyl)-1-butanol.

p is preferably 1 to 6.

n is preferably 1 to 30.

In a case where p is 2 or greater, n at the group in the round brackets (in the outer brackets) may be the same number as or different numbers from each other.

Specific examples of the polymer represented by Formula (p-2) include an adduct of 2,2-bis(hydroxymethyl)-1-butanol with 1,2-epoxy-4-(2-oxiranyl)cyclohexane [for example, trade name “EHPE3150” manufactured by Daicel Corporation)], and other polymers.

The weight-average molecular weight of the polymer (P-2) is not particularly limited, and is preferably 1,000 to 5,000, more preferably 1,500 to 4,000, and particularly preferably 2,000 to 3,000.

The content of the polymer (P) in the protective-film forming composition is not particularly limited, and is preferably 50% by mass to 100% by mass, more preferably 75% by mass to 99.99% by mass, and particularly preferably 80% by mass to 99.95% by mass with respect to the nonvolatile content (that is, the components excluding the solvent) in the protective-film forming composition.

### <Solvent>

The solvent used in the protective-film forming composition is not particularly limited as long as the solvent is capable of uniformly dissolving the contained components in the solid state at normal temperature, and an organic solvent commonly used in a chemical solution for a semiconductor lithography process is preferable. Specific examples thereof include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, and N,N-dimethylacetamide. These solvents can be used alone or in combination of two or more kinds thereof.

Among these solvents, propylene glycol monomethyl ether, propylene glycol monomethyl ether acetate, ethyl lactate, butyl lactate, and cyclohexanone are preferable. In particular, propylene glycol monomethyl ether and propylene glycol monomethyl ether acetate are preferable.

### <Crosslinking Catalyst>

The protective-film forming composition preferably contains a crosslinking catalyst in order to efficiently carry out the reactions with an oxirane ring and an oxetane ring.

Examples of the crosslinking catalyst include phosphines such as triphenylphosphine, tributylphosphine, tris(4-methylphenyl)phosphine, tris(4-nonylphenyl)phosphine, tris(4-methoxyphenyl)phosphine, tris(2,6-dimethoxyphenyl)phosphine, and triphenylphosphine triphenylborane;
quaternary phosphonium salts such as tetraphenylphosphonium chloride, tetraphenylphosphonium bromide, benzyltriphenylphosphonium chloride, benzyltriphenylphosphonium bromide, ethyltriphenylphosphonium chloride, ethyltriphenylphosphonium bromide, tetraphenylphosphonium tetraphenylborate, tetraphenylphosphonium tetra(4-methylphenyl)borate, tetraphenylphosphonium tetra(4-methoxyphenyl)borate, and tetraphenylphosphonium tetra(4-fluorophenyl)borate;
quaternary ammonium salts such as tetraethylammonium chloride, benzyltrimethylammonium chloride, benzyltrimethylammonium bromide, benzyltriethylammonium chloride, benzyltriethylammonium bromide, benzyltripropylammonium chloride, benzyltripropylammonium bromide, tetramethylammonium chloride, tetraethylammonium bromide, tetrapropylammonium chloride, and tetrapropylammonium bromide;
imidazoles such as 2-methylimidazole and 2-ethyl-4-methylimidazole;
imidazolium salts such as 2-ethyl-4-methylimidazole tetraphenylborate;
diazabicycloalkenes such as 1,8-diazabicyclo[5.4.0]-7-undecene and 1,5-diazabicyclo[4.3.0]-5-nonene; and organic acid salts of diazabicycloalkenes such as formate of 1,8-diazabicyclo[5.4.0]-7-undecene, 2-ethylhexanoate of 1,8-diazabicyclo[5.4.0]-7-undecene, p-toluenesulfonate of 1,8-diazabicyclo[5.4.0]-7-undecene, and 2-ethylhexanoate of 1,5-diazabicyclo[4.3.0]-5-nonene.

In addition, the crosslinking catalyst may be, for example, a sulfonic acid compound or a carboxylic acid compound.

Examples of the sulfonic acid compound include p-toluenesulfonic acid, pyridinium-p-toluenesulfonate, 5-sulfosalicylic acid, 4-chlorobenzenesulfonic acid, 4-hydroxybenzenesulfonic acid, pyridinium-4-hydroxybenzenesulfonate, n-dodecylbenzenesulfonic acid, 4-nitrobenzenesulfonic acid, benzenedisulfonic acid, 1-naphthalenesulfonic acid, trifluoromethanesulfonic acid, and camphorsulfonic acid.

Examples of the carboxylic acid compound include salicylic acid, citric acid, benzoic acid, and hydroxybenzoic acid.

Examples of commercially available products of the crosslinking catalyst include Hishicolin [registered trademark] PX-4C, PX-4B, PX-4MI, PX-412B, PX-416B, PX-2B, PX-82B, PX-4BT, PX-4MP, PX-4ET, and PX-4PB (all manufactured by Nippon Chemical Industrial CO., LTD.), Hokko TPP (registered trademark), TPTP (registered trademark), DPCP (registered trademark), TPP-EB (registered trademark), TPP-ZC (registered trademark), DPPB (registered trademark), EMZ-K (registered trademark), DBNK (registered trademark), TPP-MK (registered trademark), TPP-K (registered trademark), TPP-S (registered trademark), TPP-SCN (registered trademark), TPP-DCA (registered trademark), TPPB-DCA (registered trademark), TPP-PB (registered trademark), Hokko TBP-BB (registered trademark), TBPDA (registered trademark), TPPO (registered trademark), PPQ (registered trademark), TOTP (registered trademark), TMTP (registered trademark), TPAP (registered trademark), DPCP (registered trademark), TCHP (registered trademark), Hokko TBP (registered trademark), TTBuP (registered trademark), TOCP (registered trademark), DPPST (registered trademark), TBPH (registered trademark), TPP-MB (registered trademark), TPP-EB (registered trademark), TPP-BB (registered trademark), TPP-MOC (registered trademark), TPP-ZC (registered trademark), and TTBuP-K (registered trademark) (all manufactured by HOKKO CHEMICAL INDUSTRY CO., LTD.), Curezol (registered trademark) SIZ, 2MZ-H, C11Z, 1.2DEMZ, 2E4MZ, 2PZ, 2PZ-PW, 2P4MZ, 1B2MZ, 1B2PZ, 2MZ-CN, C11Z-CN, 2E4MZ-CN, 2PZ-CN, C11Z-CNS, 2PZCNS-PW, 2MZA-PW, C11Z-A, 2E4MZ-A, 2MA-OK, 2PZ-OK, 2PHZ-PW, 2P4MHZ, TBZ, SFZ, and 2PZL-T (all manufactured by SHIKOKU CHEMICALS CORPORATION), and U-CAT (registered trademark) SA1, SA102, SA102-50, SA106, SA112, SA506, SA603, SA810, SA831, SA841, SA851, 881, 5002, 5003, 3512T, 3513N, 18X, 410, 1102, 2024, 2026, 2030, 2110, 2313, 651M, 660M, 420A, DBU (registered trademark), DBN, and POLYCAT8 (all manufactured by San-Apro Ltd.).

Examples of commercially available products of the crosslinking catalyst also include K-PURE [registered trademark] CXC-1612, CXC-1614, TAG-2172, TAG-2179, TAG-2678, and TAG2689 (manufactured by King Industries, Inc.), and SI-45, SI-60, SI-80, SI-100, SI-110, and SI-150 (manufactured by SANSHIN CHEMICAL INDUSTRY CO., LTD.).

These crosslinking catalysts may be used alone or in combination of two or more kinds thereof.

The content of the crosslinking catalyst in the protective-film forming composition is not particularly limited, and is, for example, 0.005% by mass to 10% by mass and preferably 0.1% by mass to 3% by mass with respect to the polymer (P).

### <Crosslinking Agent>

Examples of the crosslinking agent contained as an optional component in the protective-film forming composition include a polymer (B) having a phenolic hydroxy group in a side chain.

In a case where the protective-film forming composition contains the polymer (B), the obtained protective film has favorable curability because the phenolic hydroxy group reacts with an oxirane ring and an oxetane ring.

The polymer (B) having a phenolic hydroxy group in the side chain preferably contains, for example, a unit structure represented by Formula (3-1).

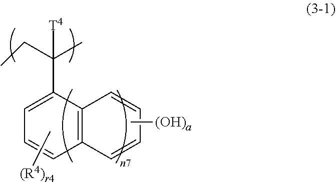

(In Formula (3-1), T4 represents a hydrogen atom or an alkyl group having 1 to 10 carbon atoms which may be substituted with a halogeno group; R⁴ represents a halogeno group, a carboxy group, a nitro group, a cyano group, a methylenedioxy group, an acetoxy group, a methylthio group, an alkoxy group having 1 to 9 carbon atoms, an amino group which may be substituted with an alkyl group having 1 to 3 carbon atoms, an alkyl group having 1 to 10 carbon atoms which may be substituted with a hydroxy group or a halogeno group; r4 represents an integer of 0 to 3; n7 represents an integer of 0 to 2; and a represents an integer of 1 to 6.)

The polymer (B) may contain one-unit structure represented by Formula (3-1) or a copolymer containing two or more-unit structures.

The polymer (B) may be a copolymer that contains a unit structure represented by Formula (3-1) and a unit structure having no phenolic hydroxy group.

Specific examples of the polymer (B) include polymers containing the unit structures described below.

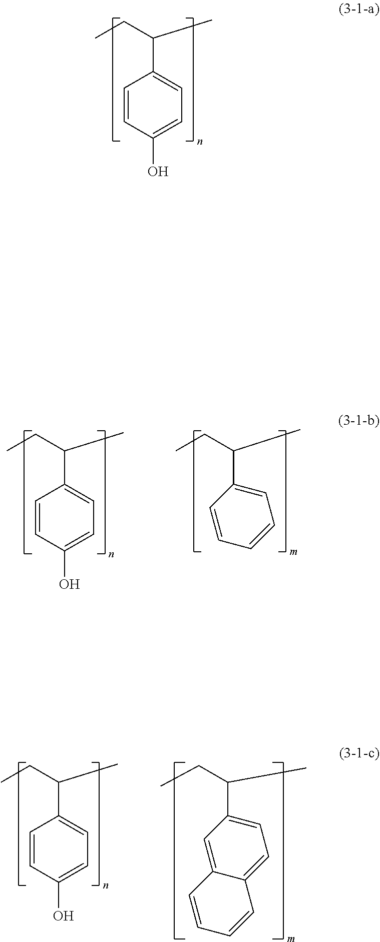

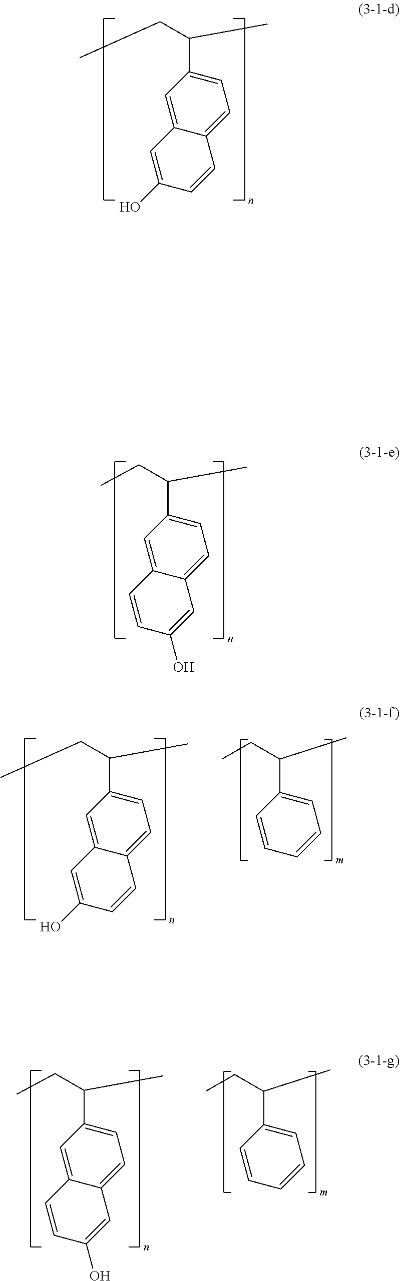

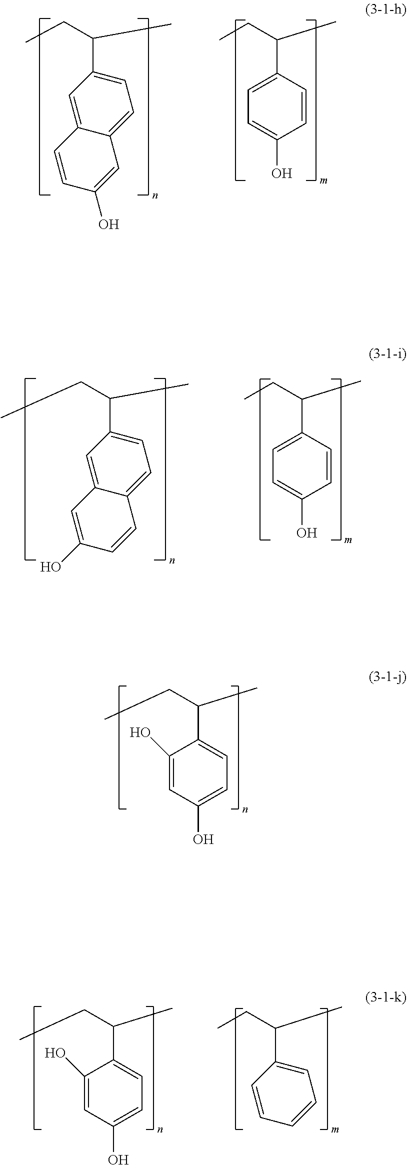

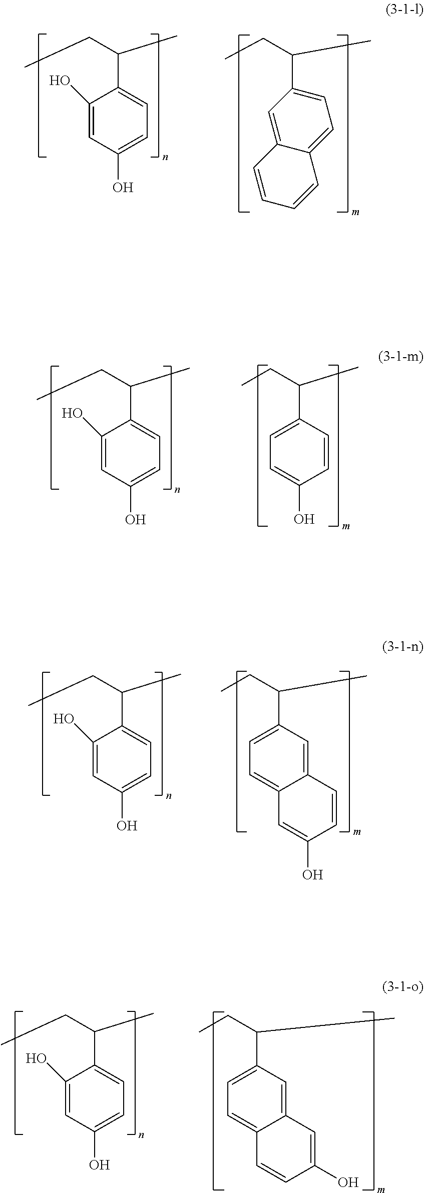

In the above formulae, m and n indicated at the side of each repeating unit represent the mole ratio of copolymerization.

The weight-average molecular weight of the polymer (B) is not particularly limited, and is, for example, 1,000 to 50,000.

The content of the crosslinking agent in the protective-film forming composition is not particularly limited, and is preferably 0.1% by mass to 50% by mass, more preferably 1% by mass to 30% by mass, and particularly preferably 10% by mass to 30% by mass with respect to the polymer (P).

### <Other Components>

A surfactant can be further added in the protective-film forming composition in order to reduce the occurrence of pinholes, striations, or defect sites, and further to improve the coatability with respect to surface unevenness. Examples of the surfactant include nonionic surfactants such as polyoxyethylene alkyl ethers such as polyoxyethylene lauryl ether, polyoxyethylene stearyl ether, polyoxyethylene cetyl ether, and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate, and sorbitan tristearate, polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate, F-TOP EF301, EF303, EF352(manufactured by Tochem Co., Ltd., trade name), fluorine-based surfactants such as MEGAFACE F171, F173, R-30, and R-40 (manufactured by DIC Corporation, trade name), Fluorad FC430 and FC431 (manufactured by Sumitomo 3M Ltd., trade name), AsahiGuard AG710, Surflon S-382, SC101, SC102, SC103, SC104, SC105, and SC106 (manufactured by Asahi Glass Co., Ltd., trade name), and organosiloxane polymer KP341 (manufactured by Shin-Etsu Chemical Co., Ltd.). The blending amount of these surfactants is usually 2.0% by mass or less, and preferably 1.0% by mass or less with respect to the total solid content of the protective-film forming composition. These surfactants may be added alone, or two or more kinds thereof may be added in combination.

The nonvolatile content (that is, components excluding the solvent) contained in the protective-film forming composition is, for example, 0.01% by mass to 10% by mass.

(Protective Film, Method for Manufacturing Substrate with Protective Film, Method for Manufacturing Substrate with Resist Pattern, and Method for Manufacturing Semiconductor Device)

A protective film of the present invention includes a baked product of a coating film formed of a protective-film forming composition.

A method for manufacturing a substrate with a protective film of the present invention includes a step of applying the protective-film forming composition of the present invention on a stepped semiconductor substrate and baking the protective-film forming composition to form a protective film.

The method for manufacturing a substrate with a resist pattern of the present invention includes steps (1) and (2) below.
Step (1): a step of applying the protective-film forming composition of the present invention on a semiconductor substrate and baking the protective-film forming composition to form a protective film as a resist under layer film
Step (2): a step of forming a resist film directly on the protective film or over the protective film, with another layer interlayered, and exposing and developing the resist film to form a resist pattern

A method for manufacturing a semiconductor device of the present invention includes processes (A) to (D) below.
Process (A): a process of forming a protective film by using the protective-film forming composition of the present invention on a semiconductor substrate having a surface on which an inorganic film is formed
Process (B): a process of forming a resist pattern directly on the protective film or over the protective film, with another layer interlayered
Process (C): a process of dry etching the protective film by using the resist pattern as a mask to expose a surface of the inorganic film
Process (D): a process of wet etching the inorganic film by using the protective film after dry etching as a mask with a semiconductor wet etching solution

The method for manufacturing a semiconductor device of the present invention further includes process (E) below.
Process (E): a process of cleaning the semiconductor substrate after wet etching with an ozonated solution

Note that, process (E) is performed before the protective film is removed from the semiconductor substrate.

Residues of the inorganic film can be removed by cleaning with the ozonated solution, for example.

Examples of the semiconductor substrate to which the protective-film forming composition of the present invention is applied include silicon wafers, germanium wafers, and compound semiconductor wafers such as gallium arsenide, indium phosphide, gallium nitride, indium nitride, and aluminum nitride.

In a case where the semiconductor substrate having a surface on which the inorganic film formed is used, the inorganic film may be formed of one or more conductive layers containing aluminum, copper, molybdenum, manganese, iron, nickel, copper, zinc, palladium, silver, cadmium, tantalum, titanium, tungsten, platinum, mercury, or an alloy thereof; nitride or silicide; doped amorphous silicon or doped polysilicon; dielectric layers such as layers formed of silicon oxide, silicon nitride, silicon oxynitride, or a metal oxide; semiconductor layers such as single crystal silicon; glass layers; quartz layers; or a combination or mixture thereof, but not limited thereto. The inorganic film preferably contains soft metals such as manganese, iron, nickel, copper, zinc, palladium, silver, cadmium, tantalum, tungsten, platinum, mercury, or alloys thereof (for example, the inorganic film is coated with a soft metal). The inorganic film may be formed by various techniques, for example, chemical vapor deposition (CVD) such as plasma-enhanced CVD, low-pressure CVD or epitaxial growth, physical vapor deposition (PVD) such as sputtering or evaporation, electroplating, or liquid coating techniques such as spin coating.

The above semiconductor substrate may be a substrate with a difference in level, in which so-called vias (holes), trenches (grooves), and other features are formed. For example, a via has a substantially circular shape when viewed from the top, the diameter of the substantially circular shape is, for example, 2 nm to 20 nm, and the depth is 50 nm to 500 nm, and a trench has, for example, a width (a recess on the substrate) of 2 nm to 20 nm, and a depth of 50 nm to 500 nm.

In the protective-film forming composition of the present invention, in a case where the weight-average molecular weight and average particle diameter of a compound contained in the composition are small, the composition can be embedded even in the substrate with the difference in level as described above without defects such as voids. It is an important characteristic that there are no defects such as voids for the next step (wet etching and dry etching of semiconductor substrate, the formation of a resist pattern) of semiconductor manufacturing.

The protective-film forming composition of the present invention is applied onto such a semiconductor substrate by an appropriate application method such as a spinner or a coater. Thereafter, the protective film is formed by baking using heating means such as a hot plate. Baking conditions are appropriately selected from a baking temperature of 100° C. to 400° C. and a baking time of 0.3 minutes to 60 minutes. The baking temperature is preferably 120° C. to 350° C. and the baking time is preferably 0.5 minutes to 30 minutes, and the baking temperature is more preferably 150° C. to 300° C., and the baking time is more preferably 0.8 minutes to 10 minutes. The thickness of the formed protective film is, for example, 0.001 μm to 10 μm, preferably 0.002 μm to 1 μm, and more preferably 0.005 μm to 0.5 μm. In a case where the temperature during the baking is lower than the above range, crosslinking is insufficient, and it may be difficult to obtain resistance of the formed protective film to a resist solvent or a basic aqueous hydrogen peroxide solution. On the other hand, in a case where the temperature during the baking is higher than the above range, the protective film may be decomposed by heat.

A resist film is formed directly on the protective film thus formed or over the protective film, with another layer interlayered, and the resist film is then exposed and developed to form a resist pattern.

The exposure is performed through a mask (reticle) for forming a predetermined pattern, and for example, i-rays, KrF excimer laser, ArF excimer laser, extreme ultraviolet rays (EUV), or electron beams (EB) are used. An alkaline developer is used for development, and a development temperature is appropriately selected from 5° C. to 50° C., and a development time is appropriately selected from 10 seconds to 300 seconds. As the alkaline developer, for example, it is possible to use alkaline aqueous solutions such as aqueous solutions of inorganic alkalis such as sodium hydroxide, potassium hydroxide, sodium carbonate, sodium silicate, sodium metasilicate, and ammonia solutions, primary amines such as ethylamine and n-propylamine, secondary amines such as diethylamine and di-n-butylamine, tertiary amines such as triethylamine and methyldiethylamine, alcoholamines such as dimethylethanolamine and triethanolamine, quaternary ammonium salts such as tetramethylammonium hydroxide, tetraethylammonium hydroxide, and choline, cyclic amines such as pyrrole and piperidine, and other alkaline aqueous solutions. Furthermore, it is also possible to add an appropriate amount of alcohols such as isopropyl alcohol or nonionic-based surfactants to the above alkaline aqueous solutions and use the resultant mixture. Among these, as the developers, it is preferable to use quaternary ammonium salts, and still more preferable to use tetramethylammonium hydroxide and choline. Furthermore, surfactants or other additives can be added to these developers. In place of the alkaline developer, it is possible to use a method of performing development with an organic solvent such as butyl acetate and developing a portion where the alkaline dissolution rate of photoresist is not improved.

Next, the protective film is dry-etched by using the formed resist pattern as a mask. At that time, when the above inorganic film has been formed on the surface of the used semiconductor substrate, the inorganic film surface is exposed, and when the above inorganic film has not been formed on the surface of the used semiconductor substrate, the semiconductor substrate surface is exposed.

Furthermore, a desired pattern is formed by wet etching with a semiconductor wet etching solution by using the protective film (together with the resist pattern in a case where the resist pattern also remains on the protective film) after dry etching as a mask.

As the semiconductor wet etching solution, it is possible to use a chemical solution commonly used to perform etching a semiconductor wafer, and for example, either a substance exhibiting acidity or a substance exhibiting basicity can be used.

Examples of the substance exhibiting acidity include hydrogen peroxide, hydrofluoric acid, ammonium fluoride, acidic ammonium fluoride, ammonium hydrogen fluoride, buffered hydrofluoric acid, hydrochloric acid, nitric acid, sulfuric acid, and phosphoric acid, or mixed solutions thereof.

Examples of the substance exhibiting basicity include a basic hydrogen peroxide solution obtained by mixing an organic amine such as ammonia, sodium hydroxide, potassium hydroxide, sodium cyanide, potassium cyanide, or triethanolamine with a hydrogen peroxide solution to adjust pH to basic. Specific examples thereof include SC-1 (ammonia-hydrogen peroxide solution). In addition, it is possible to use, as a chemical solution for wet etching, those capable of adjusting pH to basic, for example, those obtained by mixing urea and a hydrogen peroxide solution and heating the mixture to cause thermal decomposition of the urea by heating, thereby generating ammonia and finally adjusting pH to basic.

Among these, an acidic hydrogen peroxide solution or a basic hydrogen peroxide solution is preferable.

These chemical solutions may contain an additive such as a surfactant.

The use temperature of the semiconductor wet etching solution is desirably 25° C. to 90° C., and still more desirably 40° C. to 80° C. The wet etching time is desirably 0.5 minutes to 30 minutes, and still more desirably 1 minute to 20 minutes.

The method for cleaning the semiconductor substrate after wet etching with an ozonated solution is not particularly limited, and examples thereof include a method for immersing the semiconductor substrate in an ozonated solution, a method for spraying an ozonated solution onto the surface of the semiconductor substrate, and other methods.

The ozone concentration of the ozonated solution is not particularly limited, and is preferably 5 ppm by mass to 100 ppm by mass, and more preferably 10 ppm by mass to 50 ppm by mass.

The use temperature of the ozonated solution is desirably 20° C. to 50° C., and still more desirably 20° C. to 40° C. The cleaning time with the ozonated solution is desirably 0.5 minutes to 60 minutes, and still more desirably 10 minutes to 40 minutes.

Cleaning with water may be further performed following the cleaning with the ozonated solution. Examples of the water include ultrapure water.

### EXAMPLES

Next, the contents of the present invention will be specifically described with reference to Examples, but the present invention is not limited thereto.

The weight-average molecular weight of each compound in the present specification shown below is a measurement result by gel permeation chromatography (hereinafter, abbreviated as GPC). For the measurement, a GPC apparatus manufactured by Tosoh Corporation was used, and measurement conditions and other settings are as follows.
Column temperature: 40° C.
Solvent: Tetrahydrofuran (THF)
Flow rate: 1.0 ml/min
Standard sample: polystyrene (manufactured by Tosoh Corporation)

### <Explanation of Terms>

PGME: Propylene glycol monomethyl ether
PGMEA: Propylene glycol monomethyl ether acetate

### Synthesis Example 1

A solution of 1.45 g of 1-butoxyethyl methacrylate, 1.30 g of glycidyl methacrylate (manufactured by Tokyo Chemical Industry Co., Ltd.), 2.88 g of methyl methacrylate (manufactured by Tokyo Chemical Industry Co., Ltd.), 0.38 g of azobisisobutyronitrile (AIBN) (manufactured by Tokyo Chemical Industry Co., Ltd.), and 14.0 g of PGMEA was added to a dropping funnel, and added dropwise to a reaction flask into which 10.0 g of PGMEA was added at 60° C. under a nitrogen atmosphere, and heated and stirred for 24 hours to obtain a polymer solution. A weight-average molecular weight Mw measured by GPC in terms of polystyrene was 28,000.

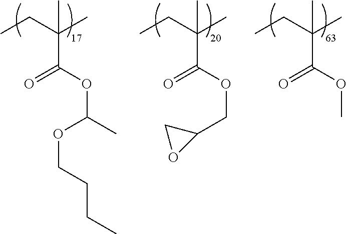

### Example 1

1.71 g (30% by mass PGMEA solution, a weight-average molecular weight of 2,659) of an adduct of 2,2-bis(hydroxymethyl)-1-butanol with 1,2-epoxy-4-(2-oxiranyl)cyclohexane EHPE3150 (the product manufactured by Daicel Corporation, corresponding to Formula (a-2)), 0.13 g of VP-2500 (the product manufactured by Nippon Soda Co., Ltd., corresponding to Formula (a-3)), a weight-average molecular weight of 3687), 0.0076 g of 1B2PZ (the product manufactured by Shikoku Chemicals Corporation, corresponding to Formula (a-4)), 0.0005 g of R-40-LM (DIC Corporation), 12.3 g of PGMEA, and 5.81 g of PGME were mixed to obtain a solution with a solid content of 3.2% by mass. The solution was filtered by using a polytetrafluoroethylene microfilter having a pore size of 0.2 μm to prepare a protective-film forming composition.

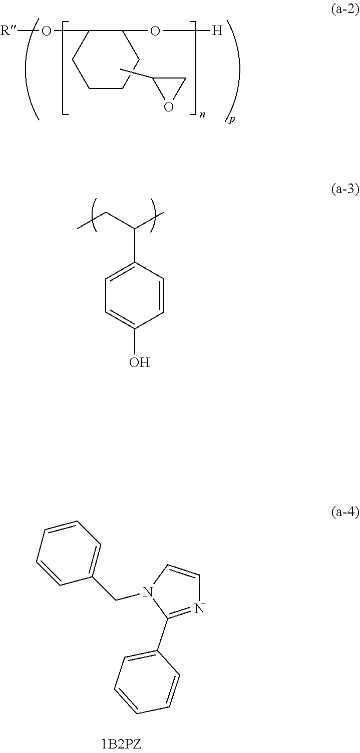

### Example 2

2.16 g (30% by mass PGMEA solution, a weight-average molecular weight of 2,659) of an adduct of 2,2-bis(hydroxymethyl)-1-butanol with 1,2-epoxy-4-(2-oxiranyl)cyclohexane EHPE3150 (the product manufactured by Daicel Corporation, corresponding to Formula (a-2)), 0.019 g of K-PURE (registered trademark) TAG-2689 (the product manufactured by King Industries, Inc.) serving as a thermal acid generator, 0.0006 g of R-40-LM (DIC Corporation), 12.0 g of PGMEA, and 5.81 g of PGME were mixed to obtain a solution with a solid content of 3.2% by mass. The solution was filtered by using a polytetrafluoroethylene microfilter having a pore size of 0.2 μm to prepare a protective-film forming composition.

### Example 3

3.42 g (18.7% by mass PGMEA solution, a weight-average molecular weight of 28,000) of the polymer solution synthesized in Synthesis Example 1, 0.0006 g of R-40-LM (DIC Corporation), 10.8 g of PGMEA, and 5.8 g of PGME were mixed to obtain a solution with a solid content of 3.2% by mass. The solution was filtered by using a polytetrafluoroethylene microfilter having a pore size of 0.2 μm to prepare a protective-film forming composition.

### Comparative Example 1

2.88 g (30% by mass PGMEA solution, a weight-average molecular weight of 3,100) of an epoxy novolac resin EOCN-104S (the product manufactured by Nippon Kayaku Co., Ltd., corresponding to Formula (a-5)), 0.086 g of VP-2500 (the product manufactured by Nippon Soda Co., Ltd., corresponding to Formula (a-3), a weight-average molecular weight of 3,687), 0.086 g of K-PURE (registered trademark) TAG-2689 (the product manufactured by King Industries, Inc.) serving as a thermal acid generator, 0.0007 g of R-40-LM (DIC Corporation), 18.31 g of PGMEA, and 8.71 g of PGME were mixed to obtain a solution with a solid content of 3.2% by mass. The solution was filtered by using a polytetrafluoroethylene microfilter having a pore size of 0.2 μm to prepare a protective-film forming composition.

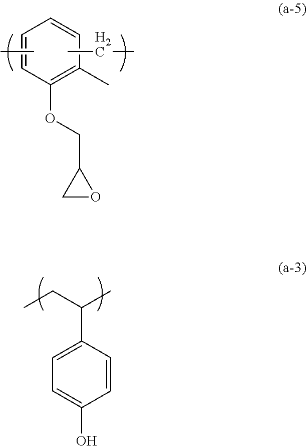

### (Resistance Test to Acidic Aqueous Hydrogen Peroxide Solution)

Each of the protective-film forming compositions prepared in Examples 1 to 3 and the protective-film forming composition prepared in Comparative Example 1 was applied by a spinner to a silicon substrate having a surface on which a titanium nitride film was formed. Each of the composition-applied substrates was baked on a hot plate at 250° C. for 1 minute to form a coating film (protective film, a film thickness of 80 nm) formed of each of the protective-film forming compositions. The prepared coating film was immersed in an acidic aqueous hydrogen peroxide solution (50° C.) having a composition shown in the following Table 1, and thereafter, cleaned with water and dried, and the state of the coating film was visually observed and evaluated. The case where the resistance was good was evaluated as “o”, and the case where the resistance was insufficient was evaluated as “x” The results are shown in Table 2 below.

TABLE 1

| | | Aqueous | |
|---|---|---|---|
| | Aqueous | hydrogen | |
| | hydrochloric | peroxide | |
| | acid solution | solution of 33% | |
| | of 35% by mass | by mass | Ultrapure water |
| Composition of | 20 ml | 20 ml | 100 ml |
| acidic aqueous | | | |
| hydrogen | | | |
| peroxide | | | |
| solution | | | |
| (total 140 ml) | | | |

TABLE 2

| | | | Comparative |
|---|---|---|---|
| Example 1 | Example 2 | Example 3 | Example 1 |
| ◯ | ◯ | ◯ | ◯ |

From the results in Table 2 above, it was found that the coating films of the protective-film forming compositions prepared in Examples 1 to 3 and the protective-film forming composition prepared in Comparative Example 1 exhibited good resistance to the acidic aqueous hydrogen peroxide solution.

### (Resistance Test to Ozonated Solution)

Each of the protective-film forming compositions prepared in Examples 1 to 3 and the protective-film forming composition prepared in Comparative Example 1 was applied by a spinner to a silicon substrate having a surface on which a titanium nitride film was formed. Each of the composition-applied substrates was baked on a hot plate at 250° C. for 1 minute to form a coating film (protective film, a film thickness of 80 nm) formed of each of the protective-film forming compositions.

The silicon substrate on which the prepared coating film was formed was placed in a container containing the ozonated solution (an ozone concentration of 20 ppm by mass, normal temperature). Then, in order to keep the ozonated solution in the container fresh, the container was continuously charged with the ozonated solution (an ozone concentration of 20 ppm by mass) while continuously discharging the same amount of the ozonated solution. This state was maintained for 30 minutes. After 30 minutes, the ozonated solution in the container was replaced with ultrapure water. Thereafter, the container was continuously charged with the ultrapure water while continuously discharging the same amount of the ultrapure water. This state was maintained for 5 minutes. The silicon substrate on which the coating film was formed was taken out from the container and dried. Thereafter, the state of the coating film after drying was visually observed and evaluated.

The case where the resistance was good was evaluated as “o”, and the case where the resistance was insufficient was evaluated as “x”. The results are shown in Table 3 below.

TABLE 3

| | | | Comparative |
|---|---|---|---|
| Example 1 | Example 2 | Example 3 | Example 1 |
| ◯ | ◯ | ◯ | X |

From the results in Table 3 above, it was found that the coating films produced by using the protective-film forming compositions prepared in Examples 1 to 3 exhibited the improved resistance to the ozonated solution as compared to the coating film produced by using the protective-film forming composition prepared in Comparative Example 1.

1. A protective-film forming composition for forming a protective film that protects an inorganic film formed on a surface of a semiconductor substrate against wet etching, the composition comprising:
a polymer that contains no aromatic ring in a main chain and contains at least one of an oxirane ring and an oxetane ring; and a solvent.

2. The protective-film forming composition according to claim 1, wherein the polymer satisfies at least one of (i) and (ii) shown below:
(i) containing at least one of a group represented by Formula (Ox-1) and a group represented by Formula (Ox-2) as a group containing the oxirane ring; and
(ii) containing a group represented by Formula (Ox-3) as a group containing the oxetane ring, 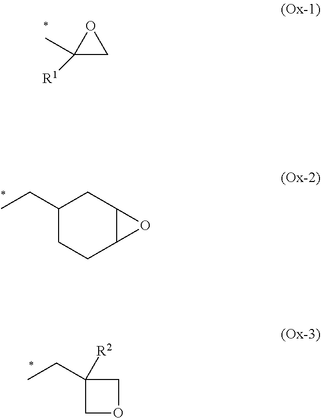
wherein, * represents a bond; and R¹ and R² each independently represent a hydrogen atom, a methyl group, or an ethyl group.

3. The protective-film forming composition according to claim 1, wherein the polymer is at least one of a polymer (P-1) that is obtained from at least a compound having a polymerizable unsaturated double bond and a polymer (P-2) that is represented by Formula (p-2), 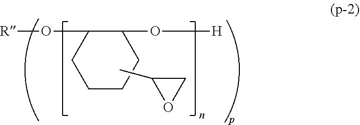
wherein, R″ is a group obtained by removing p number of hydroxyl groups (—OH) from a structural formula of a p-hydric alcohol; and p and n each represent an integer of 1 or greater.

4. The protective-film forming composition according to claim 3, wherein the polymer (P-1) contains a repeating unit represented by Formula (p-1), 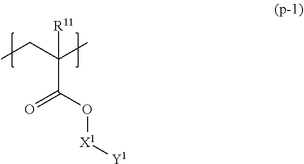
wherein, R¹¹ represents a hydrogen atom or a methyl group; Y¹ represents any one of Formula (Ox-1), Formula (Ox-2), or Formula (Ox-3); when Y¹ is Formula (Ox-1), X¹ represents a methylene group; and when Y¹ is Formula (Ox-2) or (Ox-3), X¹ represents a single bond, 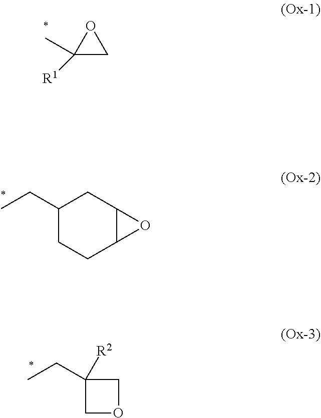
wherein, * represents a bond; and R¹ and R² each independently represent a hydrogen atom, a methyl group, or an ethyl group.

5. The protective-film forming composition according to claim 1, further comprising a crosslinking catalyst.

6. The protective-film forming composition according to claim 1, further comprising a crosslinking agent.

7. A protective film against a semiconductor wet etching solution, wherein the protective film includes a baked product of a coating film formed of the protective-film forming composition according to claim 1.

8. A method for manufacturing a substrate with a protective film, the method comprising a step of applying the protective-film forming composition according to claim 1 on a stepped semiconductor substrate and baking the protective-film forming composition to form a protective film.

9. A method for manufacturing a substrate with a resist pattern used in semiconductor manufacturing, the method comprising:
a step of applying the protective-film forming composition according to claim 1 on a semiconductor substrate and baking the protective-film forming composition to form a protective film as a resist under layer film; and
a step of forming a resist film directly on the protective film or over the protective film, with another layer interlayered, and exposing and developing the resist film to form a resist pattern.

10. A method for manufacturing a semiconductor device, the method comprising a step of forming a protective film by using the protective-film forming composition according to claim 1 on a semiconductor substrate having a surface on which an inorganic film is formed, forming a resist pattern directly on the protective film or over the protective film, with another layer interlayered, dry etching the protective film by using the resist pattern as a mask to expose a surface of the inorganic film, and performing wet etching on the inorganic film by using the protective film after the dry etching as a mask with a semiconductor wet etching solution.
